(19) United States
(12) Patent Application Publication
(10) Pub. No.: US 2006/0001447 A1
(43) Pub. Date: Jan. 5, 2006

(54) Level shifting circuit between isolated systems

(75) Inventors: Klaas-Jan De Langen, Sunnyvale, CA (US); Balwinder Singh, Union City, CA (US); Edmond Toy, Sunnyvale, CA (US)

Correspondence Address: PHILIPS ELECTRONICS NORTH AMERICA CORPORATION;INTELLECTUAL PROPERTY & STANDARDS, 1109 MCKAY DRIVE, M/S-41SJ, SAN JOSE, CA, 95131, US

(73) Assignee: Koninklijke Philips Electronics N.V., BA Eindhoven (NL)

(21) Appl. No.: 10/535,557

(22) PCT Filed: Nov. 15, 2003
(86) PCT No.: PCT/IB03/05177

§ 371 Date: May 18, 2005

Related U.S. Application Data
(60) Provisional application No. 60/427,422, filed on Nov. 18, 2002.
(60) Provisional application No. 60/499,197, filed on Aug. 28, 2003.

(51) Int. Cl. H03K 19/0175

(52) U.S. Cl. 326/80

(57) ABSTRACT

A level shifting circuit (20, 30) couples an input current (Iin) from one system to another, isolated, system, by driving a single load (L) via one or more current mirrors of a common type. In a first embodiment (20), two similar type (either N-type or P-type) current mirrors (M1,M2;M3,M4) provide output current (Iout1, Iout2) to a common load. Diodes (D1,D2) are used to split the input current (Iin1, Iin2) between the two current mirrors during normal, non-faulty conditions, and to turn off either one of the two current mirrors during a fault condition to permit proper operation in the presence of a fault. In a second embodiment (30), a single current mirror (M1,M2) mirrors the input current (Iin) to the output load (L), and a pair of diodes (D1,D2) selects which of the isolated systems to use as the power source in the event of a fault.

This invention relates to the field of electronics, and in particular to a level-shifting circuit that provides an interface between and among two or more isolated systems.

Isolated systems are commonly used for improved fault tolerance in bus systems and networks, wherein a fault in one system, such as a voltage shorted to ground, does not necessarily cause a fault in the other, isolated, system. Automotive networks, for example, commonly provide isolated systems for safety equipment, such as airbag deployment systems.

FIG. 1 illustrates a conventional level shifting circuit 10 that couples an input signal Iin of a first system (not shown) to a pair of voltage outputs Vout1 and Vout2 of a second system (also not shown). The first and second systems are isolated, in that they each have independent ground systems. The first system has a ground reference of Vgnd1, and the second system has a ground reference of Vgnd2, which may differ from Vgnd1. Such a circuit 10 is disclosed in U.S. Pat. No. 6,154,061, “CAN BUS DRIVER WITH SYMMETRICAL DIFFERENTIAL OUTPUT SIGNALS”, issued on 28 Nov. 2000 to Hendrik Boezen, Martinus Bredius, Aloysius J. M. Boomkamp, Cecilius G. Kwakemaat, and Abraham K. Van Den Heuvel, and in U.S. Pat. No. 6,452,418 “LEVEL SHIFTER WITH INDEPENDENT GROUNDS AND IMPROVED EME-ISOLATION”, issued 17 Sep. 2002 to Balwinder Singh, Klaas-Jan De Langen, and Martijn Bredius, both of which patents are incorporated by reference herein.

In a non-fault mode, both ground references Vgnd1 and Vgnd2 are nominally at the same potential. In this non-fault mode, Vdd1 will be substantially greater than Vgnd2, and Vdd2 will be substantially greater than Vgnd1, and therefore diodes D1 and D2 will be forward biased and allow conduction. The input current Iin is mirrored by both current mirrors M1, M2 and M3, M4, to produce output currents Iout1 and Iout2, respectively, because both diodes D1 and D2 are conducting. Nominally, Iout1 will equal Iout2, assuming that both current mirrors match well, and therefore there is no overall current flow between the isolated systems. Note, however, that N-channel devices are used in current-mirror M1, M2 and P-channel devices are used in current mirror M3, M4, which complicates the task of matching the high-frequency response of the current mirrors over a range of temperature and process variations. When current flows between the grounds of two systems, electromagnetic emissions from the systems increase.

If a fault causes the ground potentials Vgnd1 and Vgnd2 to differ, one of two possibilities occur. If Vgnd1 approaches or exceeds Vdd2, diode D1 enters a non-conductive state and blocks Iout1; or, if Vgnd2 approaches or exceeds Vdd1, diode D2 enters a non-conductive state and blocks Iout2. In either state, at least one of the currents Iout1 or Iout2 flows, so that the input signal Iin is coupled to either Vout1 or Vout2.

Because the input signal Iin may be coupled to either Vout1 or Vout2 or both, depending upon whether a fault occurs, and the particular effects of such a fault, a combining circuit (not shown) is required to determine a single-output, or differential-output, corresponding to the input Iin, for coupling to subsequent circuitry in the isolated system. The combining of these signals Vout1, Vout2 to produce a common output corresponding to the input current Iin is particularly difficult if the input and output signals are analog signals.

It is an object of this invention to provide a level shifting circuit for use between isolated systems that produces a single output voltage at one of the isolated systems corresponding to an input current at the other isolated system. It is a further object of this invention to provide a level shifting circuit for use between isolated systems that couples an input current of one system to an output voltage of the other system that facilitates the minimization of current flow between the two systems.

These objects and others are achieved by a level shifting circuit for coupling an input current from one system to another, isolated, system, that drives a single load via one or more current mirrors of a common type. In a first embodiment, two similar type (either N-type or P-type) current mirrors provide output current to a common load. Diodes are used to split the input current between the two current mirrors during normal, non-faulty conditions, and to turn off either one of the two current mirrors during a fault condition to permit proper operation in the presence of a fault. In a second embodiment, a single current mirror mirrors the input current to the output load and a pair of diodes selects which of the isolated systems to use as the power source in the event of a fault. A variety of techniques are presented for minimizing the current flow between the two systems, to thereby minimize electromagnetic emissions (ME) from the level shifting circuit.

FIG. 1 illustrates an example circuit diagram of a prior art level shifting circuit for coupling signals between two isolated systems.

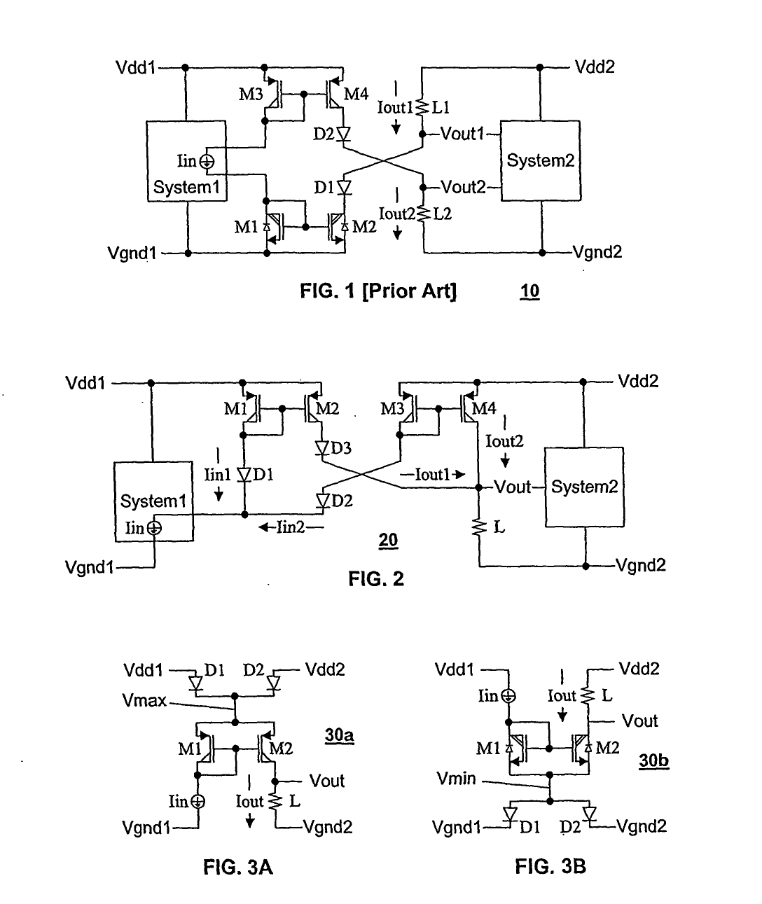

FIG. 2 illustrates an example circuit diagram of a level shifting circuit for coupling signals between two isolated systems.

FIGS. 3A and 3B each illustrates an example circuit diagram of another level shifting circuit for coupling signals between two isolated systems.

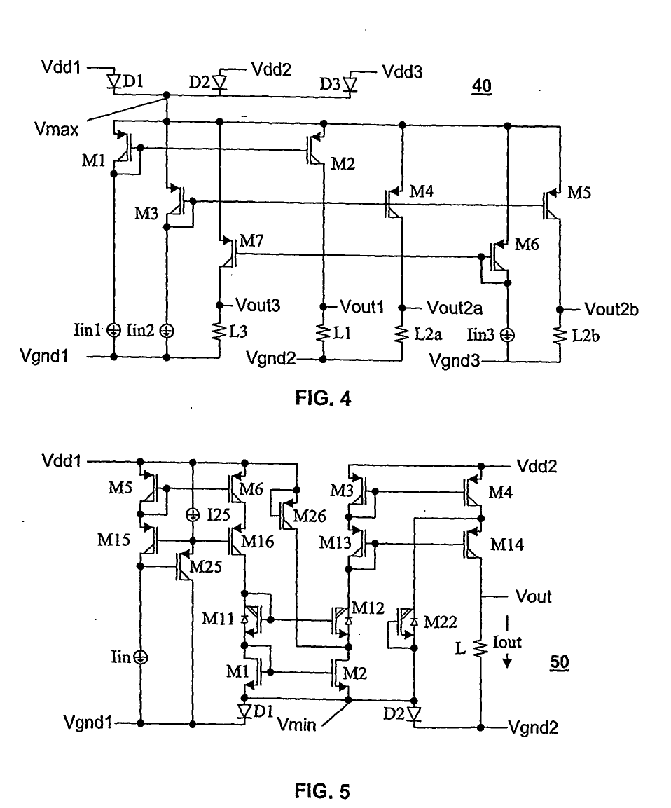

FIG. 4 illustrates an example circuit diagram of a level shifting circuit for coupling signals between and among multiple isolated systems.

FIG. 5 illustrates an example circuit diagram of a level shifting circuit that is particularly well suited for coupling an analog signal between two isolated systems.

FIG. 6 illustrates an example circuit diagram of a level shifting circuit that is particularly well suited for coupling a digital signal between two isolated systems.

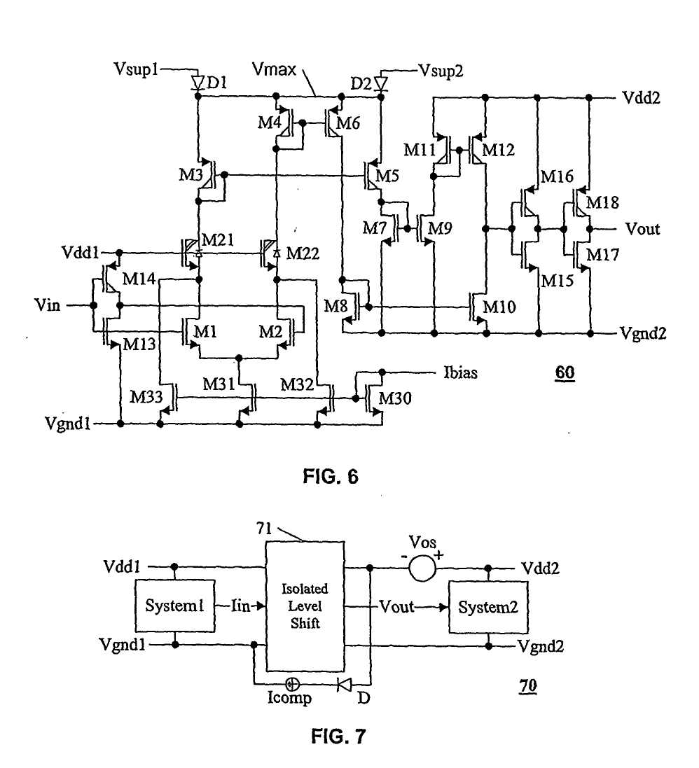

FIG. 7 illustrates an example block diagram of a compensated isolated level shifting circuit for coupling signals between two isolated systems.

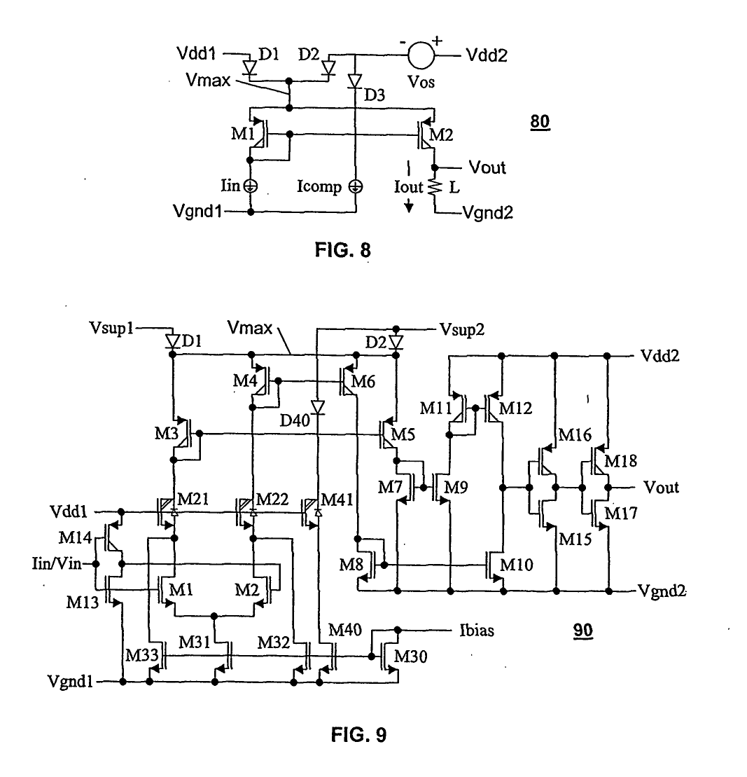

FIG. 8 illustrates an example circuit diagram of a compensated level shifting circuit for coupling signals between two isolated systems.

FIG. 9 illustrates an example circuit diagram of a differential compensated level shifting circuit for coupling signals between two isolated systems.

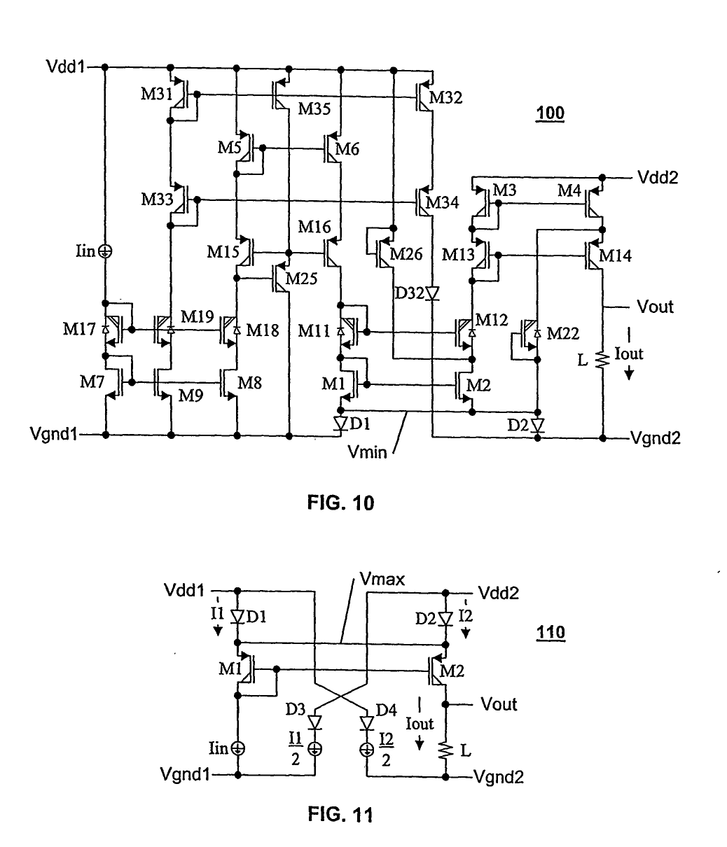

FIG. 10 illustrates an example circuit diagram of a compensated level shifting circuit that is particularly well suited for coupling analog signals between isolated systems.

FIG. 11 illustrates an example circuit diagram of an alternative compensating level shifting circuit for coupling signals between two isolated systems.

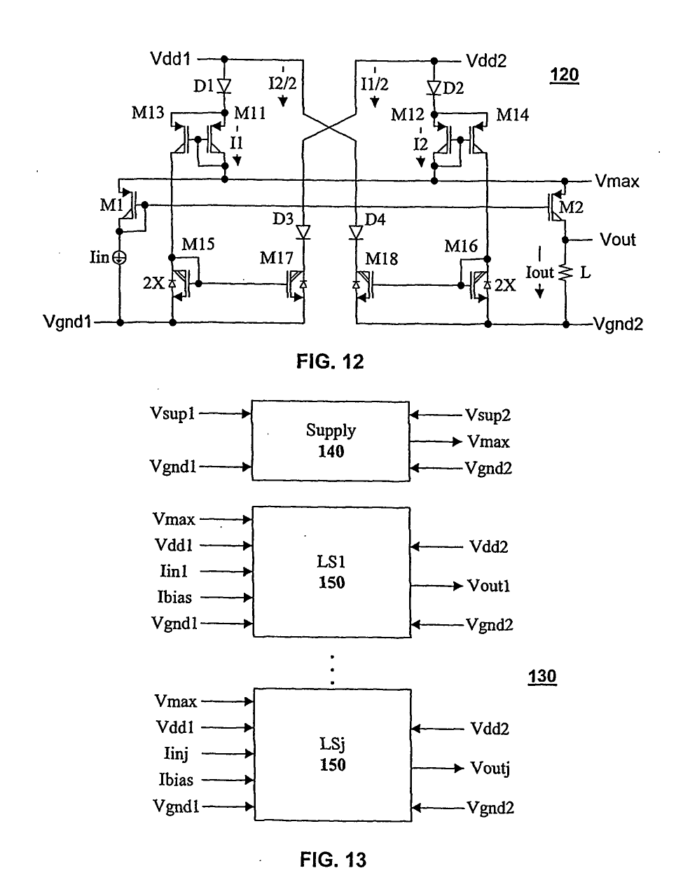

FIG. 12 illustrates an example implementation of a level shifting circuit for coupling signals between two isolated systems.

FIG. 13 illustrates an example block diagram of a level shifting system for coupling multiple signals between two isolated systems.

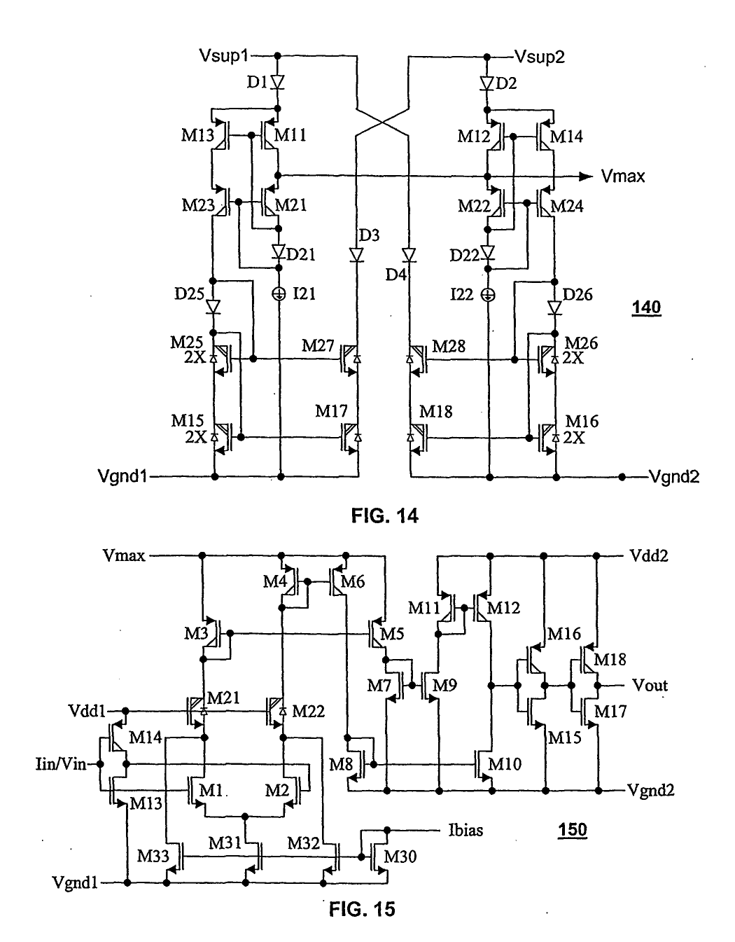

FIG. 14 illustrates an example circuit diagram of a power supply, with compensation, for use in a level shifting system.

FIG. 15 illustrates an example circuit diagram of a level shifting circuit for use in a level shifting system.

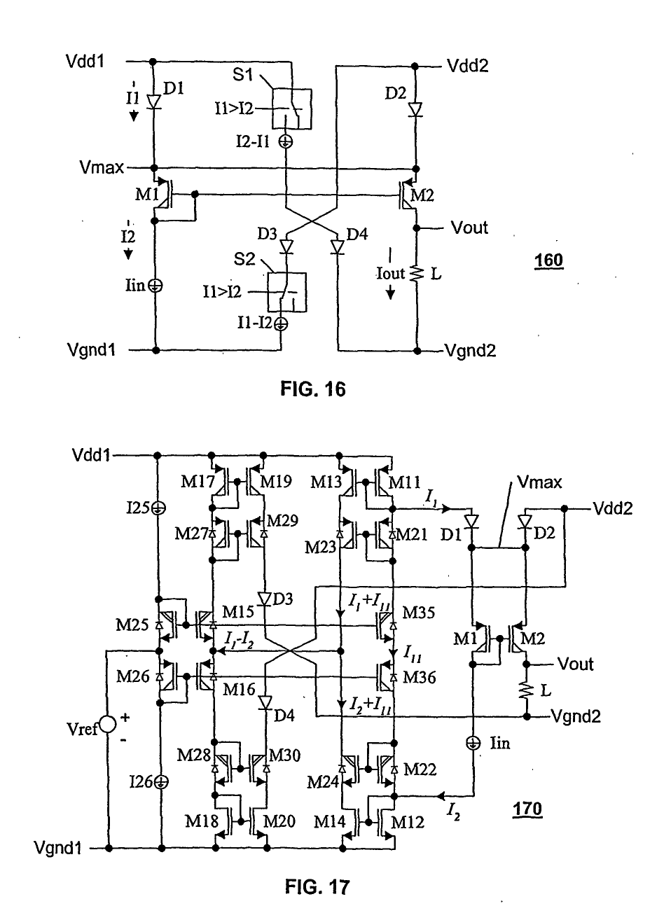

FIG. 16 illustrates an example block diagram of another compensated level shifting circuit.

FIG. 17 illustrates an example embodiment of a compensated level shifting circuit.

FIG. 2 illustrates an example circuit diagram of a level shifting circuit 20 for coupling signals between two isolated systems. The input system includes voltage references Vdd1 and Vgnd1, and the output system includes voltage references Vdd2 and Vgnd2.

In the normal, non-faulty operation of circuit 20, the input current Iin is split into two currents Iin1 and Iin2, each providing the input current to a corresponding current mirror M1, M2 and M3, M4, respectively. Each of these current mirrors M1, M2, and M3, M4 comprise P-type devices, and each provides current Iout1, Iout2, respectively, to a common load L, to produce a voltage output Vout relative to the second ground potential Vgnd2. If the current mirrors M1, M2 and M3, M4 are well matched, there is no net current flow between the systems. Because both current mirrors M1, M2, and M3, M4 are of the same type, current matching can be more easily achieved over a wide range of temperature, compared to the circuit 10 in FIG. 1.

If, due to a fault, Vgnd1 rises and approaches or exceeds Vdd2, diode D2 turns off and decouples current mirror M3, M4 from the input. The full input current Iin is then mirrored by current mirror M1, M2 to the load L. If, due to a fault, Vgnd2 rises and approaches or exceeds Vdd1, diode D1 turns off and decouples mirror M1, M2 from the input. The full current Iin is then mirrored by current mirror M3, M4 to the load L.

A complementary circuit configuration to that of FIG. 2, using N-channel current mirrors, and with the current source Iin and the load L in series between the reference voltages Vdd1 and Vdd2 and the current mirrors, can be provided as well.

FIGS. 3A and 3B each illustrates an example circuit diagram of another level shifting circuit 30a, 30b for coupling signals between two isolated systems. Circuit 30a illustrates a level shifter that uses P-channel devices, and circuit 30b illustrates its complementary circuit, which uses N-channel devices.

Each circuit 30a, 30b uses a single current mirror M1, M2 to mirror the input current Iin to the output load L. Each circuit 30a, 30b uses a pair of diodes D1, D2 to select which system supplies the current Iout. In circuit 30a, Vmax is the higher of Vdd1 and Vdd2; in circuit 30b, Vmin is the lower of Vgnd1 and Vgnd2. In this manner, the current Iout is provided regardless of the voltage difference between the two isolated systems. Preferably, and particularly for analog signal coupling, the choice of using circuit 30a, 30b is made so as to minimize the switching of the diodes, based on the expected voltage differences between the isolated systems during normal, non-faulty, operation. If it is common, for example, that one of the reference voltages Vdd1, Vdd2 is consistently larger than the other, while the ground potentials Vgnd1, Vgnd2 are approximately equal, the circuit of 30a would be preferred, because the diode D1, D2 at the consistently higher voltage Vdd1, Vdd2 would be consistently turned on. Alternatively, if one of the grounds Vgnd1, Vgnd2 consistently floats at a higher potential than the other, the circuit of 30b would be preferred, because the diode D1, D2 at the lower voltage Vgnd1, Vgnd2 would be consistently turned on. If the relative voltages are unpredictable, the circuit 30b would generally be preferred, for the inherently faster switching characteristics of N-type devices. Other characteristics of these circuits may suggest a preference of one over the other, as well.

FIG. 4 illustrates an example circuit diagram of a level shifting circuit 40 for coupling signals between and among three multiple isolated systems. Reference voltage pairs Vdd1-Vgnd1, Vdd2-Vgnd2, and Vdd3-Vgnd3 each form one of the three isolated voltage systems. This circuit is illustrated using P-channel devices; its complement, using N-channel devices, may also be used. The principles of this circuit 40 may be extended to any number of multiple isolated systems.

The diode arrangement D1, D2, D3 selects the highest voltage Vmax from among the isolated reference voltages Vdd1, Vdd2, Vdd3. This voltage Vmax provides the output current to each of the loads L1, L2a, L2b, and L3, via the current mirrors M1, M2; M3, M4; M3, M5; and M6, M7, respectively. Preferably, one of the reference voltages Vdd1, Vdd2, Vdd3 is biased relative to the other two so that the corresponding diode D1, D2, D3, respectively, is continuously on, to avoid diode switching during normal, non-faulty, operation.

Current inputs Iin1 and Iin2 and load L3 are illustrated as being referenced to the first isolated ground Vgnd1; loads L1 and L2a are illustrated as being referenced to the second isolated ground Vgnd2; and current input Iin3 and load L2b are illustrated as being reference to the third isolated ground Vgnd3.

The current input Iin1 relative to Vgnd1 is mirrored by current mirror M1, M2 to produce a current in load L1 to produce an output voltage Vout1 relative to Vgnd2. The current input In2 relative to Vgnd1 is mirrored by current mirrors M3, M4 and M3, M5 to produce a current in load L2a and a current in load L2b, to produce an output voltage Vout2a relative to Vgnd2 and an output voltage Vout2b relative to Vgnd3, respectively. In like manner, the current input Iin3 relative to Vgnd3 is mirrored by current mirror M6, M7 to produce a current in load L3 to produce an output voltage Vout3 relative to Vgnd1.

The following example circuits of FIGS. 5 and 6 are provided to illustrate how the operation of the circuits 20, 30a, 30b, and 40 may be further enhanced with respect to noise that may be introduced via changes in the supply reference voltages. The remaining figures illustrate techniques for minimizing current flow between the systems.

FIG. 5 illustrates an example circuit diagram of a level shifting circuit 50 that is particularly well suited for coupling an analog signal between two isolated systems. The current mirror M1, M2 and diodes D1, D2 correspond to the level-shifting circuit 30b of FIG. 3B. The input current Iin is mirrored by current mirror M5, M6, by current mirror M1, M2, and finally by current mirror M3, M4, yielding an output current Iout that is substantially equal to the input current Iin. Diodes D1 and D2 select the lower of the two ground potentials Vgnd1 and Vgnd2 creating Vmin. Therefore the input current is always transferred to the output independent of the difference between the two ground potentials. Each of the current mirrors M1, M2; M3, M4; M5, M6 is cascoded using transistors M11, M12; M13, M14; and M15, M16, respectively, to increase the supply rejection. Thus, the influence of changes in the difference between the two ground potentials is reduced. In addition, devices M22 and M26 have been added to cancel signals introduced by the gate-drain capacitance of M12 and M16, respectively, as a result of the changes in the difference of the ground potentials. Suppose, for example, that Vgnd1 is larger than Vgnd2 so that D1 is blocking while D2 is conducting. In this case transistors M1 and M11 are connected to Vgnd2 by D2. When Vgnd1 and Vdd1 are changing with respect to Vgnd2 the gate-drain capacitance of M16 is injecting current at the input of cascoded current mirror M1, M2; M11, M12. The gate-drain capacitance of M26 is subtracting a similar signal at the output of the current mirror M1, M2 cancelling the influence of the gate-drain capacitance of M16. Similarly, the gate-drain capacitance of M22 cancels the influence of the gate-drain capacitance of M12 when Vdd2 changes with respect to Vmin. Transistor M25, biased by current source I25, isolates the gate-drain capacitance of M16 from the input current.

FIG. 6 illustrates an example circuit diagram of a level shifting circuit 60 that is particularly well suited for coupling a digital signal between two isolated systems. The core of the digital level-shift circuit comprising M1, M12 and M21, M22 is completely differential to obtain high power-supply rejection in order to cope with changes in one ground potential with respect to the other ground potential. Another advantage of the fully-differential level shift is that the digital switching does not influence the current drawn from the supplies Vdd1 and Vdd2 or the current delivered to the grounds Vgnd1 and Vgnd2, so that the current flowing between the two grounds is not affected by the digital switching. This is an important advantage over the circuit discussed in the prior art and yields improved EME performance.

At the heart of the circuit are two P-channel current mirrors M3, M5 and M4, M6 similar to the level shifter 30a shown in FIG. 3A. These current mirrors perform the level shift of the current signals using Vmax created by diodes D1 and D2, from supply voltages Vsup1 and Vsup2 that are each higher than Vdd1 and Vdd2, respectively. The differential currents for the level-shift current mirrors are produced by differential pair M1, M2. Transistor M1 is driven by the digital input signal Vin while M2 is driven by the inverted input signal created by inverter M13, M14. The differential stage M1, M2 drives the level-shift current mirrors M3, M5 and M4, M6 via cascodes M21 and M22. These cascodes are DMOS transistors that can handle high voltages at the drain connection while limiting the voltage across the low-voltage CMOS transistors M1 and M2. Therefore, the circuit can still operate with large voltage differences between Vgnd1 and Vgnd2. The level-shifting current mirrors M3, M5 and M4, M6 then drive current mirrors M7, M9 and M8, M10, respectively. Finally, the drain current of M9 is mirrored by current mirror M11, M12 and added to the drain current of M10 producing a single-ended signal within the range of the digital supply Vdd2 referenced to the second ground potential Vgnd2. This signal is buffered by inverters M15, M16 and M17, M18 creating the output signal Vout. Current sources M32 and M33 have been added to maintain a minimum bias current in transistors M3 through M12 and M21, M22 improving the speed of the circuit. As an example consider the case when the input signal Vin is high. In that case the gate of M1 is high and the gate of M2 is low. Therefore, transistors M21, M3, M5, M7, M9, M11 and M12 are biased at a high current while transistors M2, M22, M4, M6, M8 and M10 are biased at a low current so that the voltage at the drains of M10 and M12 goes up and therefore also the output OUT goes high.

The following figures present a variety of techniques for minimizing current flow between isolated systems, herein referred to as “compensation” techniques.

FIG. 7 illustrates an example block diagram of a compensated isolated level shifting circuit 70 for coupling signals between two isolated systems. The isolated systems include a first system with reference voltages Vdd1 and Vgnd1, and a second system with reference voltages Vdd2 and Vgnd2. The circuit 70 includes a voltage source Vos that is configured to offset the biasing of the level shifter 71. This offset voltage Vos biases the level shifter 71 sufficiently so that the voltage source Vdd1 consistently provides power to the level shifter 71, to avoid transient switching. A current generator Icomp provides a compensating current from the second system to the first system that offsets the current that is provided by the first voltage source to the second system, to provide a substantially zero net current flow between the systems. The offset voltage Vos could also be configured to bias the level shifter 71 so that Vdd2 provides the power to the level shifter 71, and so on. In like manner, the current generator Icomp could be configured to provide current from the first system to the second, or a combination of compensation generators could be used to substantially equalize the current flow from each system, and so on.

FIG. 8 illustrates an example circuit diagram of a compensated level shifting circuit 80 for coupling signals between two isolated systems. The core of this example circuit 80 corresponds to circuit 30a of FIG. 3A. The voltage source Vos offsets the voltage Vdd2 so that diode D2 is consistently turned off, and diode D1 is consistently turned on, during normal fault-free operation, thereby minimizing switching transients. Current generator Icomp provides a current from the second system (Vdd2) to the first system (Vgnd1) that, over a wide frequency range, matches the current Iout that is provided by the first system (Vdd1) to the load L in the second system. In this manner, the net current flow between the two systems is substantially zero.

FIG. 9 illustrates an example circuit diagram of a differential compensated level shifting circuit 90 for coupling signals between two isolated systems that embodies the principles presented in the circuit 80 of FIG., 8. The core of this circuit 90 corresponds to the example circuit 60 of FIG. 6, discussed above. The compensation circuitry includes diode D40 and transistors M40 and M41. It is assumed in this example circuit 90 that Vsup1 is configured to be higher than Vsup2, and therefore Vsup1 provides the current to the circuit 90 during non-fault operation. The bias current Ibias controls the current from Vsup2 through the compensation circuitry to Vgnd1 to compensate for the current that is provided by Vsup1 to Vgnd2 via M5 and M6.

FIG. 10 illustrates an example circuit diagram of a compensated level shifting circuit 100 that is particularly well suited for coupling analog signals between isolated systems. The core of this example circuit 100 corresponds to example circuit 50 in FIG. 5, discussed above. In this circuit the input current Iin is first duplicated using cascoded current mirror M7, M9; M17, M19. One output at the drain of M18 is used as input for the current mirror M5, M6; M15, M16; M15, M25. The second output at the drain of M19 is mirrored by cascoded current mirror M31, M32; M33, M34 so that a current is flowing from Vdd1 via blocking diode D32 to Vgnd2. In this case it is assumed that during normal operation Vgnd2 is larger than Vgnd1 so that D2 blocks and the drain current of M2 flows from Vdd2 via D1 to Vgnd1. This current is compensated by the current created by M32.

FIG. 11 illustrates an example circuit diagram of an alternative compensating level shifting circuit 110 for coupling signals between two isolated systems. This example circuit 110 provides the general principle for automatic current compensation using this example technique. Assume a first example wherein Vdd1 is larger than Vdd2, so that only current I1 is provided to the level shifting circuit 110. Half of this current I1 will flow through each leg of the current mirror M1, M2, the current through M2 (of magnitude I1/2) flowing into the second system via the load L to Vgnd2. The current generator I1/2 draws this same amount of compensation current from Vdd2 to Vgnd1 via diode D3. In like manner, when Vdd2 provides the current I2 to the level shifting circuit 110, current generator I2/2 draws the compensation current from Vdd1 to Vgnd2 via diode D4.

FIG. 12 illustrates an example implementation of a level shifting circuit 120 for coupling signals between two isolated systems, using the principles discussed with regard to the example circuit 110 of FIG. 11. The basic level-shift circuit, again, consists of current mirror M1, M2, input current Iin and load L, while diodes D1, D2 select the highest supply voltage from Vdd1 and Vdd2. By placing diode-connected transistors M11 and M12 between the diodes and current mirror M1, M2 the currents I1, I2 flowing through the diodes D1, D2 are measured and provided to current mirrors M15, M17 and M16, M18. The W/L ratio of transistors M15 and M16 are configured to be twice that of transistors M17 and M18, so that half of the measured currents I1 and I2 are drawn from the supplies Vdd1 and Vdd2 via blocking diodes D4 and D3. The total current drawn from Vdd1 is equal to two times I1 plus half I2. Assuming the W/L ratios of transistors M1 and M2 are equal so that Iout equals Iin, the current delivered to Vgnd1 via M1 is equal to half the sum of I1 and I2, and the current delivered to Vgnd1 via M15 and M17 is one and a half I1, for a total of two times I1 plus half I2. Thus, the current to Vgnd1 is substantially identical to the current provided by Vdd1, and thus substantially zero net current flows from the first system of Vdd1-Vgnd1. Similarly, the current delivered to Vgnd2 is substantially equal to the current provided by Vdd2. Although the circuit is more complicated than the previously discussed compensation circuit and consumes more bias current, the compensation is automatic so that the compensation circuit does not have to be adapted according to the number of level-shift circuits. Thus, multiple signals can be transferred using only one current compensation arrangement, as illustrated in FIGS. 13-15.

FIG. 13 illustrates an example block diagram of a level shifting system 130 for coupling multiple signals between isolated systems using the principles discussed above regarding circuits 110 and 120 of FIGS. 11 and 12. The system 130 includes a common compensated voltage supply 140, and one or more level shifting modules 150. The supply 140 provides the supply voltage Vmax to each module 150, and also includes current measuring and compensating circuitry, as detailed below. Each level shifting module 150, illustrated further in FIG. 15, couples an input signal Iini to a corresponding output Vouti (i=1 to j), using the principles discussed with regard to the example circuit 60 of FIG. 6.

FIG. 14 illustrates an example circuit diagram of a power supply 140, with compensation, for use in a level shifting system 130. This circuit employs the current measuring and compensating techniques discussed with regard to circuits 110 and 120 of FIGS. 11 and 12. In this circuit all current mirrors M11-M18 are cascoded by transistors M21-M28. Operation at reasonably low supply voltages is maintained by biasing the cascodes inside the gate-source voltages of the current-mirror transistors M11-M18. Instead of placing the cascades M21-M28 on top of the current-mirror transistors M11-M18, the gates of the cascodes M21-M28 are connected to the gates of the current-mirror transistors M11-M18 via diodes D21, D22, D25, and D26. The diodes generate a voltage drop so that the drain-source voltage of the current-mirror transistors is sufficient for proper operation. Also, supply Vmax is provided from the drain of M11 and M12 instead of the gate of M11 and M12 or the gate of M21 and M22. That is, the current mirror M11, M13, M21, M23 and M12, M14, M22, M24 can be considered as folded-cascode current mirrors. Thus, the voltage drop between the Vsup1 and Vmax or Vsup2 and Vmax is limited to approximately two diode voltage drops.

FIG. 16 illustrates an example block diagram of another compensated level shifting circuit 160. In this example embodiment, two switches S1, S2 are controlled based on which system is supplying the current to the level shifting circuit 160. If Vdd1 is higher than Vdd2, diode D1 is forward biased, diode D2 is reverse biased, and current I1 flows through diode D1 to both legs of the current mirror M1, M2. The current through transistor M1 is referred to in this example circuit as I2. In this example, I1 is larger than I2, switches S1 and S2 are set as illustrated in FIG. 16, enabling the current generator I1-I2 to draw the difference current I1-I2 from source Vdd2 via D3. In this example, the total current from Vdd1 is I1, and the total current to Vgnd1 is also I1. In like manner, if Vdd2 supplies the current to the level shifter, I1 is substantially zero, I2 is greater than I1, and switches S1 and S2 are set opposite to the state illustrated in FIG. 16. In this case, Vdd2 provides current I2 to Vgnd1 via M1, and Vdd1 provides a substantially equal current I2 to Vgnd2 via D4, for a net current flow of substantially zero between the systems.

FIG. 17 illustrates an example embodiment of a compensated level shifting circuit 170, using the principles discussed with regard to the example circuit 160 of FIG. 16. The compensation circuit is shown together with a simple level-shift circuit comprising transistors M1, M2 and diodes D1, D2. The current I1 flowing through diode D1 is measured by M11 and mirrored by current mirror M11, M13, M21, M23. The current I2 flowing from the level shift into the first ground Vgnd1 is measured by M12 and mirrored by mirror M12, M14, M22, M24. The outputs of the two current mirrors at the drains of M23 and M24 are connected together yielding the difference of I1 and 12. This current difference is flowing into the source of M15 or the source of M16. When I1 is larger than I2 the current difference is flowing into the source of M16 and is mirrored by cascoded current mirror M18, M20, M28, M30. The current difference is then drawn from Vdd2 via blocking diode D4. When I2 is larger than I1 the current difference is flowing through M15 and is mirrored by cascoded current mirror M17, M19, M27, M29. Thus, the current difference is flowing into Vgnd2 via blocking diode D3. Transistors M35 and M36, connected in the same way to transistors M25 and M26 as transistors-M15 and M16, form a source of current I11 that is used to set the quiescent current in mirrors M11, M13, M21, M23 and M12, M14, M22, M24 so that both mirrors are always biased even when diode D1 is blocking. This improves the dynamic behavior. The value of I11 does not affect the current difference I1-I2 flowing into the source of M15 and M16. Current sources I25 and I26 and transistors M25 and M26 set the quiescent current for transistors M15 and M16 and also for current mirrors M18, M20, M28, M30 and M17, M19, M27, M29. Since this quiescent current is drawn substantially equally from both supplies and is delivered substantially equally to both grounds there is substantially no resulting current flowing between the two grounds. Therefore, the whole circuit is always biased and the dynamic behavior is much better than the dynamic behavior of the compensation circuits based on the first technique. Also, because the difference of currents is used, less current is consumed. The reference voltage Vref is used to bias the sources of M15 and M16 somewhere in the middle of the supply-voltage range so that M23 and M24 are properly biased. It is also possible to remove voltage source Vref and replace current source I26 by a voltage source, a number of diodes, or a few diode-connected MOS transistors.

The foregoing merely illustrates the principles of the invention. It will thus be appreciated that those skilled in the art will be able to devise various arrangements which, although not explicitly described or shown herein, embody the principles of the invention and are thus within the spirit and scope of the following claims.

1. A level shifter comprising: a pair of current mirrors that are configured to couple an input signal from a first system to a common output node (Vout) in a second system that is isolated from the first system, and a pair of diodes that are configured to decouple one of the pair of current mirrors from the input signal if a fault occurs.

2. The level shifter of claim 1, wherein the pair of current mirrors comprise transistors that are each of the same channel-type.

3. The level shifter of claim 1, wherein the pair of diodes are further configured to split current from the input signal to provide substantially half the current to each of the pair of current mirrors when the fault does not occur.

4. The level shifter of claim 1, wherein a first current mirror of the pair of current mirrors is supplied by a first reference voltage of the first system, and a second current mirror of the pair of current mirrors is supplied by a second reference voltage of the second system.

5. The level shifter of claim 4, further comprising a third diode (D3) that is configured to decouple the first current mirror from the common output node if the fault occurs.

6. The level shifter claim 1, further including a current generator is configured to provide a compensation current between the first system and the second system, to minimize a net current flow between the first system and the second system.

7. The level shifter claim 1, further including a voltage source that is configured to provide bias between the first system and the second system to minimize switching transients.

8. A level shifter for coupling an input signal in from a first system to an output node in a second system that is isolated from the first system, comprising: a current mirror that is configured to mirror current corresponding to the input signal to a load at the output node, and a pair of diodes that is configured to select a reference voltage from one of the first system and the second system to provide a net current to the current mirror.

9. The level shifter of claim 8, further including: at least one other current mirror that is configured to mirror the current corresponding to the input signal to at least one other load in at least one other system, and at least one other diode, operably coupled to the pair of diodes to form a diode network that is configured to select the reference voltage from one of the first system, the second system, and the at least one other system, to provide the net current to the current mirror.

10. The level shifter of claim 8, further including: a second current mirror that is configured to mirror another current corresponding to an input from the second system to an other load in the first system.

11. The level shifter of claim 8, wherein the current mirror comprises P-channel transistors, a first diode of the pair of diodes is arranged in series between a first supply voltage of the first system and the current mirror, and a second diode of the pair of diodes is arranged in series between a second supply voltage of the second system and the current mirror, so that the reference voltage corresponds to whichever of the first supply voltage and the second supply voltage is at a higher potential.

12. The level shifter of claim 8, wherein the current mirror comprises N-channel transistors, a first diode of the pair of diodes is arranged in series between the current mirror and a first ground voltage of the first system, and a second diode of the pair of diodes is arranged in series between the current mirror and a second ground voltage of the second system, so that the reference voltage corresponds to whichever of the first ground voltage and the second ground voltage is at a lower potential.

13. The level shifter of claim 8, further including a second current mirror that is configured to mirror a second current corresponding to an inversion of the input signal to provide a differential output in the second reference system.

14. The level shifter claim 8, further including one or more bias transistors that is configured to provide a bias current to the current mirror to enhance a switching speed of the current mirror.

15. The level shifter of claim 8, further including cascode transistors corresponding to each transistor in the current mirror.

16. The level shifter of claim 15, further including one or more current-injecting transistors that is configured to reduce the effects of gate-drain capacitance associated with one or more of the cascode transistors.

17. The level shifter claim 15, further including one or more isolation transistors that is configured to decouple the effects of gate-drain capacitance associated with one or more of the cascode transistors from the input signal.

18. The level shifter of claim 8, further including a current generator that is configured to provide a compensation current between the first system and the second system, to substantially minimize a net current flow between the first system and the second system.

19. A method of coupling an input signal from a first system to a common output node in a second system that is isolated from the first system, comprising: coupling the input signal to the common output node via a pair of current mirrors, and providing a pair of diodes that are configured to decouple one of the pair of current mirrors from the input signal if a fault occurs.

20. A method of coupling an input signal from a first system to a common output node in a second system that is isolated from the first system, comprising: mirroring current corresponding to the input signal to a load at the output node via a current mirror, and selecting a reference voltage from one of the first system and the second system via a pair of diodes, to provide a net current to the current mirror.
